(19) United States
(12) Patent Application Publication
(10) Pub. No.: US 2025/0096121 A1
(43) Pub. Date: Mar. 20, 2025

(54) TRANSISTOR DEVICE WITH REDUCED ON-RESISTANCE

(71) Applicant: Infineon Technologies Austria AG, Villach (AT)

(72) Inventors: Thomas Martin Feil, Villach (AT); Sylvain Leomant, Pörtschach am Wörther See (AT); Maximilian Rösch, St. Magdalen (AT)

(21) Appl. No.: 18/827,979

(22) Filed: Sep. 9, 2024

(30) Foreign Application Priority Data
Sep. 15, 2023 (DE) 102023124966.5

(51) Int. Cl. H01L 23/522; H01L 29/10; H01L 29/66; H01L 29/78

(52) U.S. Cl. CPC H01L 23/5228; H10D 30/0297; H10D 30/668; H10D 30/751

(57) ABSTRACT

A transistor device and a method for forming a transistor device are disclosed. The transistor device includes: a semiconductor body; first trenches extending from a first surface of the semiconductor body into the semiconductor body; second trenches extending from the first surface into the semiconductor body; a drift region adjoining each of the second trenches; source regions separated from the drift region by a respective body region; and gate electrodes arranged in the first trenches adjacent to at least one of the body regions and dielectrically insulated from the at least one of the body regions by a gate dielectric. Each of the second trenches is configured to induce a strain in regions of the drift region adjoining the respective second trench.

### TECHNICAL FIELD

This disclosure relates in general to a transistor device.

### BACKGROUND

Transistor devices, such as vertical transistor devices, are widely used as electronic switches is in various kinds of electronic applications such as, for example, power conversion circuits, motor drive circuits, or the like. In a vertical transistor device a current path essentially extends in a vertical direction of a semiconductor body in which the transistor device is integrated. Thus, when the vertical transistor device is in an on-state (switched-on state), a current flows in the vertical direction through the semiconductor body between a first load path node and a second load path node. In a MOSFET (Metal-Oxide-Semiconductor Field-Effect-Transistor), for example, the first load path node is a drain node and the second load path node is a source node.

An on-resistance of the transistor device is an electrical resistance between the first load path node and the second load path node in the on-state of the transistor device.

It is desirable to provide a vertical transistor device with a reduced on-resistance.

### SUMMARY

One example relates to a transistor device. The transistor device includes a semiconductor body, first trenches each extending from a first surface of the semiconductor body into the semiconductor body, second trenches each extending from the first surface into the semiconductor body, a drift region adjoining each of the second trenches, source regions each separated from the drift region by a respective body region, and gate electrodes. Each of the gate electrodes is arranged in one of the first trenches, is adjacent to at least one of the body regions and is dielectrically insulated from the at least one of the body regions by a gate dielectric, and each of the second trenches is configured to induce a strain in regions of the drift region adjoining the respective second trench.

Another example relates to a method. The method includes forming first trenches and second trenches in a semiconductor body each extending from a first surface of the semiconductor body into the semiconductor body, forming a drift region adjoining each of the second trenches, forming source regions each separated from the drift region by a respective body region, and forming gate electrodes. Each of the gate electrodes is formed in one of the first trenches adjacent to at least one of the body regions and dielectrically insulated from the at least one of the body regions by a gate dielectric. Forming the second trenches includes forming the second trenches such that each of the second trenches is configured to induce a strain in regions of the drift region adjoining the respective second trench.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 illustrates a vertical cross-sectional view of a transistor device with a plurality of first trenches that each include a gate electrode and a plurality of second trenches that each adjoin a drift region and are configured to induce a strain in the adjoining drift region;

FIG. 2 illustrates a modification of the transistor device according to FIG. 1;

FIG. 3 illustrates a detailed view of one section of the transistor device according to FIG. 1, to illustrate certain dimensions in the transistor device;

FIGS. 4-6 illustrate different examples of top view of the semiconductor body;

FIGS. 7A-7B schematically illustrates one example of a method for forming a second trench including a strain inducing material;

FIGS. 8-11 illustrate different examples of second trenches each including a strain inducing material;

FIG. 12 illustrates second trenches which, in addition to the strain inducing material, include a contact electrode for contacting adjoining source and body regions;

FIG. 13 illustrates one example for connecting the contact electrodes according to FIG. 12 to a source electrode of the transistor device;

FIG. 14 illustrates a top view of the transistor device according to one example; and

FIG. 15 illustrates one example for connecting a field electrode arranged in a first trench below the gate electrode to the source electrode.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

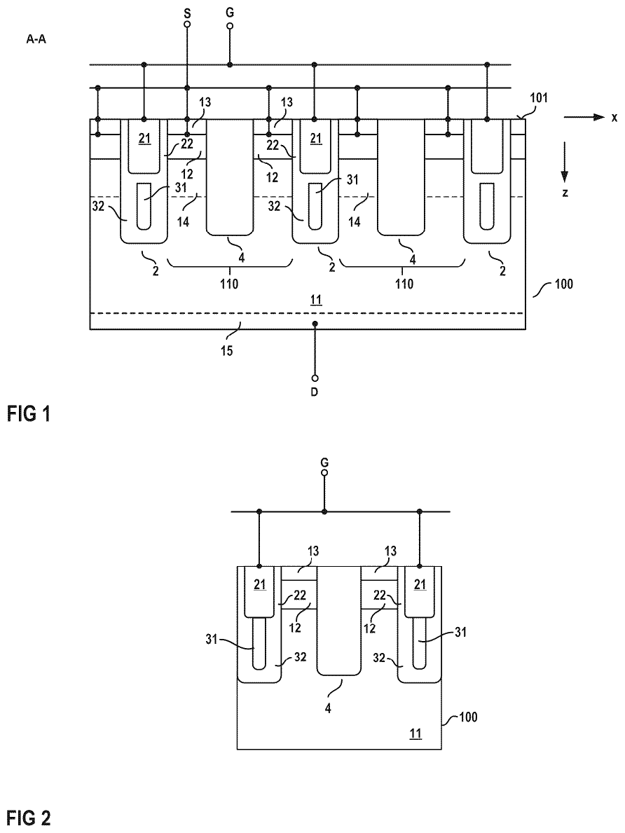

FIG. 1 shows a transistor device according to one example. More specifically, FIG. 1 shows a vertical cross-sectional view of one portion of the transistor device. The transistor device includes a semiconductor body 100. The semiconductor body 100 includes a first surface 101 and a second surface 102. The second surface 102 is opposite the first surface 101 and is spaced apart from the first surface 101 in a vertical direction z of the semiconductor body 100.

According to one example, the semiconductor body 100 is a monocrystalline semiconductor body. According to one example, the semiconductor body 100 includes monocrystalline silicon (Si) or monocrystalline silicon carbide (SiC), but may include any type of monocrystalline III-V or II-VI semiconductor material as well.

Referring to FIG. 1, the transistor device further includes a plurality of first trenches 2 each extending from the first surface 101 of the semiconductor body 100 into the semiconductor body 100, a plurality of second trenches 4 each extending from the first surface 101 into the semiconductor body 100, and a drift region 11 adjoining each of the first and second trenches 2, 4. Furthermore, the transistor device includes a plurality of source regions 13, wherein each source region 13 is separated from the drift region 11 by a respective body region 12. Each of the first trenches 2 includes a gate electrode that is arranged adjacent to at least one of the body regions 12 and is dielectrically insulated from the body region 12 by a gate dielectric 22. The first trenches 2 are also referred to as gate trenches in the following.

The gate electrodes 21 are connected to a gate node G, the source and body regions 12, 13 are connected to a source node S, and the drift region 11 is connected to a drain node D. Connections between the gate electrodes 21 and the gate node G, between the source and body regions 12, 13 on one side and the source node S on the other side, and between the drift region 11 and the drain node D are only schematically illustrated in FIG. 1. These connections may be formed using conventional wiring technology. One example for connecting the source and body regions 12, 13 to the source node S and for connecting the gate electrodes 21 to the gate node G is explained herein further below. The gate electrodes 21 include an electrically conducting material such as a metal or a doped polysilicon.

The transistor device may further include a drain region 15 adjoining the drift region 11 such that the drift region 11 is arranged between the drain region and the body regions 12. As illustrated in dashed lines in FIG. 1, the drain region 15 may adjoin the second surface 102 and be connected to the drain node D at the second surface 102. This, however, is only an example. It is also possible to form the drain region 15 spaced apart from the second surface 102 and connect the drain region 15 via a sinker to a drain electrode arranged on top of the first surface 101 at a position spaced apart from the first and second trenches 2, 4. This example is not illustrated in FIG. 1.

Each of the drift region 11, the source regions 13 and the body regions 12 is a doped region in the semiconductor body 100. The drift region 11 and the source regions 13 are doped regions of a first doping type (conductivity type) and the body regions 12 are doped regions of a second doping type complementary to the first doping type. The drain region (not illustrated) is a region of the first doping type.

The transistor device can be implemented as an N-type transistor device or as a P-type transistor device. In an N-type transistor device, the doped regions of the first doping type (drift and source regions 11, 13) are N-type regions and the doped regions of the second doping type (body regions 12) are P-type regions. In a P-type transistor device, the drift and source regions 11, 13 are P-type regions and the body regions 12 are N-type regions.

Furthermore, the transistor device can be implemented as an enhancement device or as a depletion device. In an enhancement device, each body region 12 adjoins the respective gate dielectric 22 (as illustrated in FIG. 1). In a depletion device, there is a channel region of the same doping type as the source region 13 arranged between each body region 12 and the gate dielectric 22. Such channel region, however, is not illustrated in FIG. 1.

The transistor device according to FIG. 1 can be operated in a conventional way by applying a drive voltage (gate-source voltage) between the gate node G and the source node S. The transistor device is in an on-state (conducting state) when a voltage level of the drive voltage applied between the gate node G and the source node S is such that a conducting channel is generated in each body region 12 along the respective gate dielectric 22 between the source region 13 and the drift region 11. An N-type transistor device, for example, is in the on-state when a positive drive voltage higher than the threshold voltage is applied between the gate and source nodes G, S. In the on-state, a current can flow from the source node S via the source regions 13, the conducting channels in the body regions 12, and the drift region 11 to the drain node D.

In the following, body regions 12, source regions 13, the drift region 11 and the drain region are referred to as “active device regions”. According to one example, doping concentrations of the active device regions in a silicon semiconductor body 100 are selected from the following ranges, drift region 11: between 1E15 cm⁻³ and 3E17 cm⁻³; body region 12: between 1E16 cm⁻³ and 5E18 cm⁻³; source region 13: higher than 1E19 cm⁻³; drain region 15: higher than 1E19 cm⁻³.

The second trenches 4, at least in those sections where the second trenches 4 adjoin the drift region 11, include a material that induces strain in the drift region 11 at least at an interface between the trenches 4 and the drift region 11. The second trenches 4 are also referred to as strain inducing trenches in the following. The strain generated by the second trenches 4 is such that it reduces the resistivity or increases the conductivity of the drift region 11 in those sections adjoining the second trenches 4. In this way, the on-resistance of the transistor device, which is the electrical resistance in the on-state, is reduced as compared to a conventional transistor device that is devoid of strain inducing trenches 4. More detailed examples of the strain inducing trenches 2 are explained herein further below.

The first and second trenches 2, 4 are spaced apart from each other in a lateral direction of the semiconductor body 100. A “lateral direction” is a direction that is essentially parallel to the first surface 101 and perpendicular to the vertical direction z. In the example illustrated in FIG. 1, the first and second trenches 2, 4 are spaced apart from each other in a first lateral direction x.

In order to more evenly distribute the current in the drift region 11 when the transistor device is in the on-state, the drift region 11 may include a current spreading region 14. The current spreading region 14 is optional and is therefore illustrated in dashed lines in FIG. 1. The current spreading region 14 is a portion of the drift region 11 and has a higher doping concentration than the remainder of the drift region 11. According to one example, the doping concentration of the current spreading region 14 is between 2 times and 100, in particular between 2 times and 10 times, of the doping concentration of the remainder of the drift region 11. The current spreading region 14 may adjoin the body regions 12 and extend between the first and second trenches 2, 4. Thus, in the on-state, charge carriers that are injected into the drift region 11 from the source regions 12 via the conducting channels in the body regions 12 along the gate dielectrics 22 can flow within the higher doped current spreading region 14 to the second trenches 4 and further flow in the vertical direction z in strained regions along the second trenches 4.

Referring to FIG. 1, the transistor device may further include a plurality of field electrodes 31 that are dielectrically insulated from the drift region 11 by a field electrode dielectric 32. Each of the field electrodes 31 is arranged in a respective one of the gate trenches 2 below the respective gate electrode 21. The field electrode 31 include an electrically conducting material such as a metal or doped polysilicon.

According to one example, the field electrodes 31 are connected to the source node S. In this example each field electrode 31 is spaced apart from the gate electrode 21 arranged in the same gate trench 2 and dielectrically insulated from the gate electrode 21. This is illustrated in FIG. 1.

According to another example illustrated in FIG. 2, each field electrode 31 adjoins the gate electrode 21 arranged in the same trench. In this example, the field electrodes 31 are connected to the gate node G.

In each case, the field electrodes 31, in the blocking state of the transistor device, compensate charges in the drift region 11 and, therefore, either help to increase the voltage blocking capability or decrease the on-resistance of the transistor device as compared to a transistor device without such field electrodes. This is commonly known, so that no further explanation is provided in this regard.

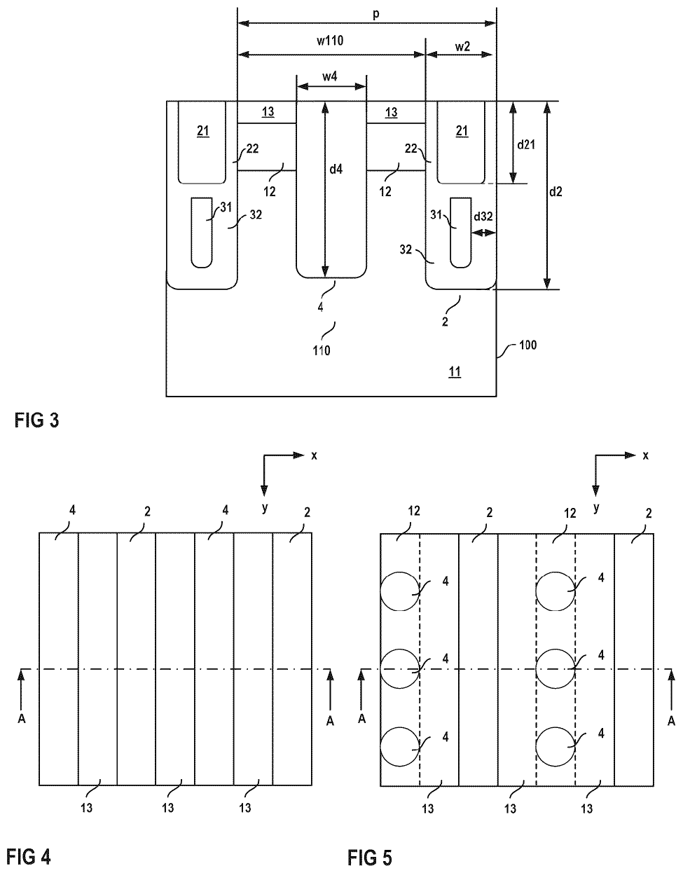

FIG. 3 shows a detailed view of one section of the semiconductor body 100 illustrated in FIG. 1, to illustrate dimensions of certain features of the transistor device. Referring to FIG. 3, the first trenches 2 have a first trench depth d2 and a first trench width w2, and the second trenches 4 have a second trench depth d4 and a second trench width d4. The “trench depth” is the dimension of the respective trench in the vertical direction z of the semiconductor body 100, and the “trench width” is the (shortest) dimension of the respective trench in the lateral direction of the semiconductor body 100. A gate electrode depth d21 is the dimension of the gate electrodes 21 in the vertical direction z.

According to one example, the second trenches 4 extend deeper into the semiconductor body than the gate electrodes 21, so that the second trench depth d4 is greater than the gate electrode depth d21, d4>d21. The second trenches 4 may extend deeper into the semiconductor body 100 than the first trenches 2, so that d4>d2, wherein the second trench depth d4 is less than 1.5 times or less than 1.2 times the first trench depth d2.

The drift region 11 has a length, which is the shortest distance of the drift region 11 between the body regions 12 and the drain region 15. The length of the drift region 11 is, inter alia, dependent on a voltage blocking capability of the transistor device. The “voltage blocking capability” of the transistor device is the maximum voltage the transistor device can withstand between the drain and source notes in the blocking state. In a transistor device comprising a silicon (Si) semiconductor body, the drift region length is approximately 10 micrometers (μm) per 100 V of voltage blocking capability. In a semiconductor device with a voltage blocking capability of 150 V, for example, the drift region length is between 10 micrometers and 15 micrometers, for example.

In a transistor device comprising a SiC semiconductor body, the drift region length is approximately 1 micrometer (μm) per 100 V of voltage blocking capability.

The absolute depths d2, d4 of the first and second trenches 2, 4 is dependent on the length of the drift region 11, for example. According to one example, the depth d2 of the first trenches 2 is between 30% and 60% of the length of the drift region 11. In a transistor device with a silicon semiconductor body 100 and a voltage blocking capability of 15 V, for example, the depth of the first trenches 2 may be selected from between 500 nanometers (nm) and 650 nanometers. In a transistor device with a silicon semiconductor body 100 and a voltage blocking capability of 150 V, for example, the depth d2 of the first trenches 2 may be selected from between 5 micrometers and 7 micrometers.

According to one example, the second trenches 4 are narrower than the first trenches 2, so that w4<w2. According to another example, the second trenches 4 are wider than the first trenches 2, so that w4>w2. According to one example, a ratio w2:w4 between the first and second trench widths is between 0.5:1 and 1:0.5, in particular between 0.7:1 and 1:0.7.

The absolute value of the trench widths w2, w4 is dependent on the voltage blocking capability of the transistor device, for example. According to one example, in a silicon-based transistor device with a voltage blocking capability of 15 V, the width w2 of the first trenches 2 is selected from between 250 nanometers and 400 nanometers. In a silicon based transistor device with a voltage blocking capability of 150 V, the width w2 of the first trenches 2 is selected from between 1.2 micrometers and 2 micrometers, for example.

In FIG. 3, w110 denotes the (shortest) distance between two neighboring first trenches 2. This distance equals a width of the mesa region 110 defined by the two neighboring trenches, so that w110 may also be referred to as mesa width. According to one example, the second trench 4 is located essentially in the middle between the neighboring first trenches 2 defining the mesa region 110. The second trench width w4 his between 0.2 times and 0.7 times, in particular between 0.4 times and 0.6 times, the mesa width w110, for example.

A pitch p of the device structure including the first and second trenches 2, 4 and the mesa regions 110 is given by the mesa width w110 plus the first trench width w2, p=w110+w2, for example.

FIG. 1 shows a vertical cross-sectional view of the semiconductor body 100. In a horizontal plane, which is a plane that is essentially parallel to the first surface 101, the first and second trenches 2, 4 may be implemented in various ways. Different examples are illustrated in FIGS. 4-6, wherein each of these figures shows a top view of the first surface 101 of one section of the semiconductor body 100.

According to one example illustrated in FIG. 4, the first and second trenches 2, 4 are elongated trenches that are essentially parallel to each other. Each of the second trenches is arranged between two neighboring first trenches, wherein the two neighboring first trenches 2 define a mesa region 110 in which the second trench 4 is arranged. In the example illustrated in FIG. 4, the first and second trenches 2, 4 are spaced apart from each other in a first lateral direction x and are elongated in a second lateral direction y.

FIG. 5 shows a modification of the example illustrated in FIG. 4. In the example illustrated in FIG. 5, the first trenches 2 are elongated trenches and the second trenches 4 are needle trenches, wherein a plurality of second trenches 4 are formed in each mesa region 110 and spaced apart from each other in the second lateral direction y.

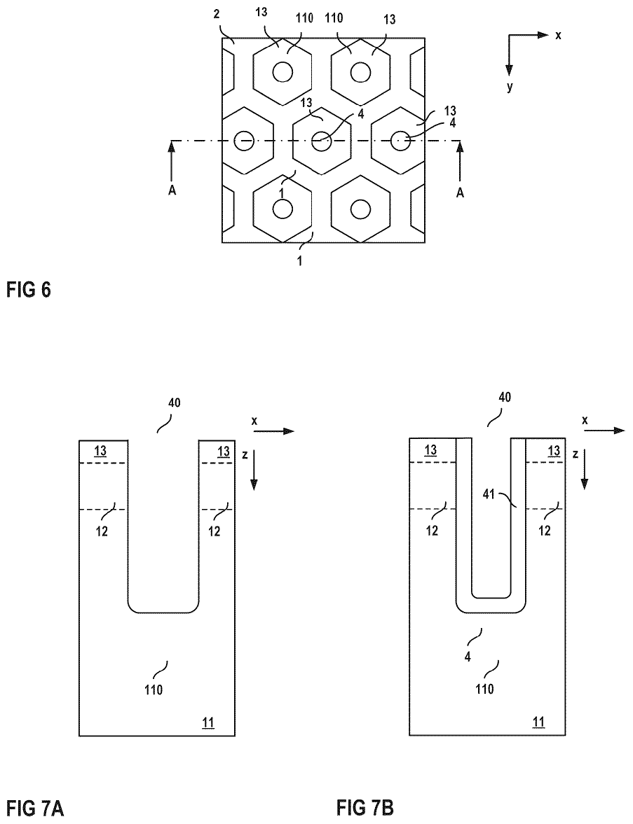

According to another example illustrated in FIG. 6, the first trenches 2 form a grid, wherein mesa regions 110 are located in openings of the grid formed by the first trenches 2. The second trenches 4 are needle trenches in this example, wherein at least one second trench 4 is arranged in each mesa region 110.

Just for the purpose of illustration, the grid illustrated in FIG. 6 is a hexagonal grid. This, however, is only an example. Other types of grids, such as a square grid, or an octagonal grid may be implemented as well.

For inducing a strain in the drift region 11 of the semiconductor body 100, the strain inducing trench 4 is at least partially filled with a strain inducing material 41 (see, e.g., FIG. 4B) that has a lower thermal expansion coefficient than the semiconductor material of the drift region 11. Silicon, for example, has a thermal expansion coefficient of 2.6E-6 K⁻¹ (2.6·1⁻⁶/K). “At least partially filled” may include that at least sidewalls and a bottom of the strain inducing trench 4 are covered by the strain inducing material, so that an interface between the drift region 11 and the strain inducing material 41 is formed.

Forming the strain inducing material 41 includes a high temperature process in which the semiconductor body 100 is heated up to temperatures of between 600° C. and 1200° C. When the semiconductor body 100 cools down after the high temperature process strain is induced in the drift region 11 due to the different thermal expansion coefficients of the semiconductor material of the drift region 11 on one side and the strain inducing material 41 on the other side.

FIGS. 7A-7B illustrate one example of a method for forming a strain inducing trench 4 that is partially filled with a strain inducing material 41. FIGS. 7A-7B show a section of the semiconductor body 100 that includes one strain inducing trench. First trenches 2 or further strain inducing trenches are not illustrated in the figures.

FIG. 7A shows the semiconductor body 100 after forming a trench 40 that extends from the first surface 101 into the semiconductor body 100. Forming the trench 40 may include a conventional etching process, such as an anisotropic etching process. Furthermore, the trench 40 may be formed before or after forming the body and source regions 12, 13 (illustrated in dashed lines in FIGS. 4A-4B) in the drift region 11. Forming the body and source regions 13, 12 may include at least one of an implantation and a diffusion process. Processes for forming the body and source regions 12, 13 are commonly known, so that no further explanation is provided in this regard.

FIG. 7B shows the trench 40 after partially filling the trench 40 with a strain inducing material 41 that covers sidewalls and a bottom of the trench 40 to form the strain inducing trench 4.

The strain inducing material 41 may be implemented and formed in various ways. According to one example, the strain inducing material 41 is a semiconductor oxide, such as silicon oxide. Forming a strain inducing oxide material 41 may include a deposition process in which the material is deposited on sidewalls and the bottom of the trench 40. According to another example, forming a strain inducing oxide material includes a thermal oxidation process in which the sidewalls and the bottom of the trench 40 are oxidized to form strain inducing oxide material. According to another example, forming a strain inducing oxide material 41 includes forming a first layer by a thermal oxidation process and a second layer on top of the first layer by a deposition process.

According to another example, the strain inducing material 41 includes a carbon containing material such as, for example, silicon oxycarbide (SiOC). SiOC may be formed using a plasma-enhanced chemical vapor deposition (PECVD) process at a temperature of about 600° C. Other examples of the strain inducing material 41 include, but are not restricted to, silicon carbide (SiC), glass such as silicon dioxide (SiO₂), or diamond. These materials may be formed in a deposition process. SiC, for example, may be formed using a PECVD process, and diamond a be formed using a chemical vapor deposition (CVD) process.

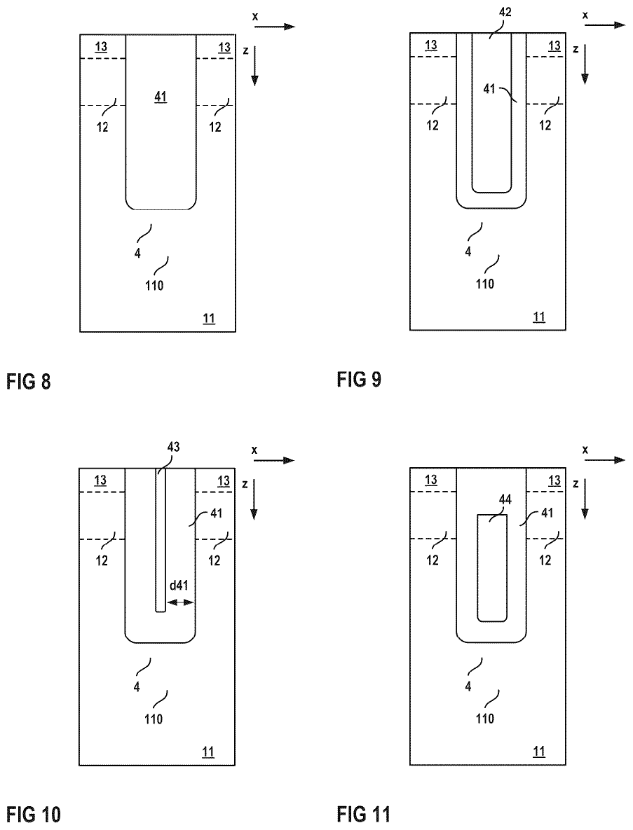

Referring to the above, the strain inducing material 41 at least partially fills the trench 40. According to one example illustrated in FIG. 8, the trench 40 is completely filled with the same strain inducing material 41, wherein the strain inducing material is selected from one of the strain inducing materials explained herein before.

According to another example illustrated in FIG. 9, the strain inducing trench 4 includes a first strain inducing material 41 covering the sidewalls and the bottom of the trench, and a second strain inducing material 42 different from the first strain inducing material 41. The second strain inducing material 42 is formed on top of the first strain inducing material 41 and fills a residual trench that remains after forming the first strain inducing material 41. Each of the first and second strain inducing materials 41, 42 is selected from the strain inducing materials explained herein before.

According to another example illustrated in FIG. 10, the strain inducing trench 4, in addition to the strain inducing material 41, includes an electrically conducting material 43 that is formed on top of the strain inducing material 41 and fills a residual trench that remains after forming the strain inducing material 41. The electrically conducting material 43 may include a metal or doped polysilicon.

According to one example, the electrically conducting material 43 is floating, that is, the electrically conducting material is neither connected to the source node S, the gate node G or the drain node D. In this example, the conducting material 42 simply acts as a filling material.

According to another example explained herein further below, the electrically conducting material 43 is connected to the source node S. In this example, however, the strain inducing material 41 arranged between the electrically conducting material 43 and the drift region 11 is thicker than the field dielectric 33, so that the electrically conducting material 43 has little, if any, effect on forming the electric field in the drift region 11. According to one example, a thickness d41 of the strain inducing material 41 is at least 1.2 times a thickness d32 (see FIG. 3) of the field dielectric 32.

According to one example, the thickness of the field dielectric 32 is dependent on the voltage blocking capability of the transistor device. In a transistor device with a voltage blocking capability of 15 V, for example, the thickness of the field dielectric 32 is selected from between 30 nanometers and 50 nanometers, for example. In a transistor device with a voltage blocking capability of 150 V, for example, the thickness of the fields dielectric 32 is selected from between 600 nanometers and 800 nanometers, for example.

According to another example illustrated in FIG. 11, the strain inducing material 41 forms a void 44 in the strain inducing trench 4.

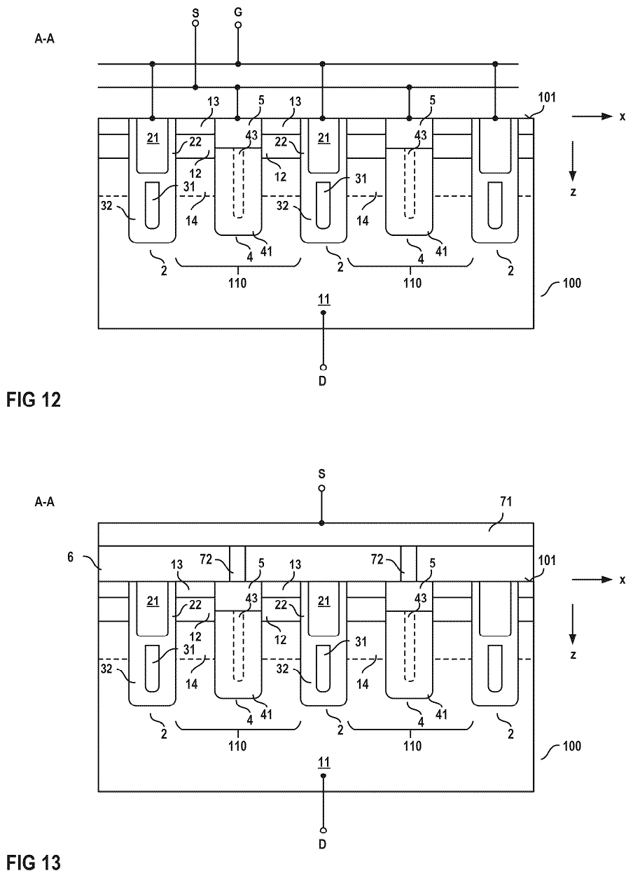

Referring to the above, the body and source regions 12, 13 are connected to the source node S. According to one example illustrated in FIG. 12, contact electrodes 5 are formed in the strain inducing trenches 4 and adjoin the source and body regions 12, 13. The contact electrodes 5, which include an electrically conducting material such as a metal or a doped polysilicon, are connected to the source node S1. As explained with reference to FIG. 10, an electrically conducting material 43 may be formed in the strain inducing trenches 4 on top of the strain inducing material 41. The electrically conducting material 43 (illustrated in dashed lines in FIG. 12) arranged in each of the strain inducing trenches 4 may adjoin the respective contact electrode 5 and therefore be connected to the source node S.

FIG. 13 illustrates one example for connecting the contact electrodes 5 to the source node S. In the example illustrated in FIG. 13, the transistor device includes a source electrode (source metallization) 71 that is formed on top of an insulating layer 6 formed on top of the first surface 101 of the semiconductor body 100. Electrically conducting vias 72 extend through the insulating layer 6 from the source electrode 71 down to the contact electrodes 5 and connect the contact electrodes 5 to the source electrode 71. The source electrode 71 forms the source node S or is connected to the source node S of the transistor device.

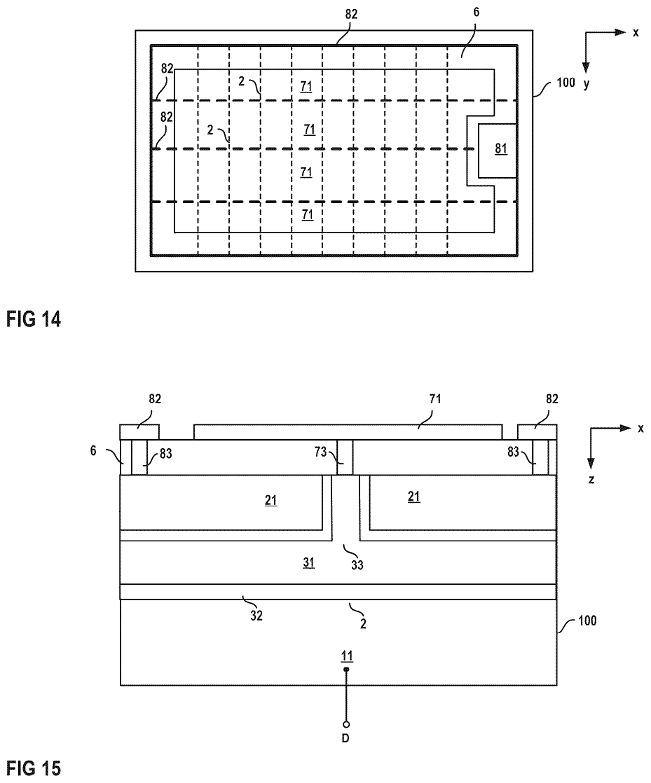

Connections between the gate electrodes 21 and the gate node G are not illustrated in FIG. 13. One example for connecting the gate electrodes 21 to the gate node G is illustrated in FIG. 14. FIG. 14 shows a top view of the transistor device. More specifically, FIG. 14 shows a top view of the semiconductor body 100 with the source metallization 71. Examples of the gate trenches 2 and their position below the source metallization 71 are illustrated in dashed lines in FIG. 14. In this example, the gate trenches 2, below the source metallization 71, extend beyond the source metallization 71 and are connected to a gate runner 82. The gate runner 82 is formed on top of the insulating layer 6 and is connected to a gate pad 81. The gate pad 81 is connected to the gate node G or forms the gate node G of the transistor device.

The transistor device according to FIG. 14 may include only one source metallization 41. This, however, is only an example. According to another example the transistor device includes several source metallizations 71, which are each connected to the source node S, and includes two or more gate runners 82, which are each connected to the gate pad 51. Each of the gate runners 82 is arranged between neighboring source metallizations and is spaced apart from the source metallizations 71. Such additional gate runners 82 are illustrated in dashed lines in FIG. 14.

Additional gate runners 82 and several source metallization 71 may be implemented in a transistor device that includes field electrodes 31 that are connected to the source node S. This is explained with reference to FIG. 15.

FIG. 15 shows vertical cross-sectional view of one gate trench 2 that includes gate electrodes 21 and a field electrode 31 connected to the source node S. FIG. 15 shows a vertical cross-sectional view of the gate trench 2 in a section plane extending in a longitudinal direction of the gate trench 2. Referring to FIG. 15, the field electrode 31 includes a contact section 33 that extends to the first surface 101 and is connected to the source metallization 71 through an electrically conducting via 73. The contact section 33 is dielectrically insulated from neighboring gate electrodes 21 arranged in the same trench 2. Each of the gate electrodes 21 is connected to a source runner 82 through a respective electrically conducting via 83. The gate runner 82 and the source metallizations are formed on top of the insulating layer 6.

Some of the aspects explained above are briefly summarized in the following with reference to numbered examples.

Example 1. A transistor device, including: a semiconductor body; first trenches each extending from a first surface of the semiconductor body into the semiconductor body; second trenches each extending from the first surface into the semiconductor body; a drift region adjoining each of the second trenches; source regions each separated from the drift region by a respective body region; and gate electrodes, wherein each of the gate electrodes is arranged in one of the first trenches, is adjacent to at least one of the body regions, and is dielectrically insulated from the at least one of the body regions by a gate dielectric, wherein each of the second trenches is configured to induce a strain in regions of the drift region adjoining the respective second trench.

Example 2. The transistor device of example 1, wherein the second trenches are at least partially filled with a strain inducing material.

Example 3. The transistor device of example 1 or 2, wherein the strain inducing material has a lower thermal expansion coefficient than a semiconductor material of the semiconductor body.

Example 4. The transistor device of example 3, wherein the strain inducing material includes at least one of a semiconductor oxide, silicon carbide, carbon, or glass.

Example 5. The transistor device of any one of examples 1 to 4, wherein the first trenches define a plurality of mesa regions in the semiconductor body, and wherein at least one second trench is arranged in each of the mesa regions.

Example 6. The transistor device of any one of examples 1 to 5, wherein the first trenches are essentially parallel to one another, and wherein each mesa region is formed between a respective pair of neighboring ones of the first trenches.

Example 7. The transistor device of example 1 to 5, wherein the first trenches form a grid, and wherein each mesa region is formed in a grid opening.

Example 8. The transistor device of any one of examples 5 to 7, wherein each mesa region includes at least one of the source regions and the respective body region.

Example 9. The transistor device of any one of the preceding examples, further including: field electrodes arranged in the first trenches adjacent to the drift region and dielectrically insulated from the drift region by a field electrode dielectric.

Example 10. The transistor device of example 9, wherein the strain inducing material is thicker than the field electrode dielectric.

Example 11. The transistor device of any one of examples 2 to 10, wherein the strain inducing material entirely fills the second trenches.

Example 12. The transistor device of any one of examples 2 to 10, wherein the strain inducing material includes: a first strain inducing material covering sidewalls and bottoms of the second trenches; and a second strain inducing material different from the first strain inducing material and formed on top of the first strain inducing material.

Example 13. The transistor device of any one of examples 2 to 10, wherein the second trenches further include an electrically conducting material formed on top of the strain inducing material.

Example 14. The transistor device of any one of examples 2 to 10, wherein the second trenches each further include a void surrounded by the strain inducing material.

Example 15. The transistor device of any one of examples 1 to 14, further including: contact electrodes arranged in the second trenches, wherein each of the contact electrodes adjoins at least one source region and at least one body region and is connected to a source node of the transistor device.

Example 16. A method for forming a transistor device, wherein the method includes: forming first trenches and second trenches in a semiconductor body each extending from a first surface of the semiconductor body into the semiconductor body; forming a drift region adjoining each of the second trenches; forming source regions each separated from the drift region by a respective body region; and forming gate electrodes, wherein each of the gate electrodes is formed in one of the first trenches adjacent to at least one of the body regions and dielectrically insulated from the at least one of the body regions by a gate dielectric, and wherein forming the second trenches includes forming the second trenches such that each of the second trenches is configured to induce a strain in regions of the drift region adjoining the respective second trench.

Example 17. The method of example 16, wherein forming the second trenches includes at least partially filling the second trenches with a strain inducing material.

Example 18. The method of example 17, wherein at least partially filling the second trenches with the strain inducing material includes a high temperature process, and wherein the strain inducing material has a lower thermal expansion coefficient than a semiconductor material of the semiconductor body.

What is claimed is:

1. A transistor device, comprising:
a semiconductor body;
first trenches extending from a first surface of the semiconductor body into the semiconductor body;
second trenches extending from the first surface into the semiconductor body;
a drift region adjoining each of the second trenches;
source regions separated from the drift region by a respective body region; and
gate electrodes arranged in the first trenches adjacent to at least one of the body regions and dielectrically insulated from the at least one of the body regions by a gate dielectric,
wherein each of the second trenches is configured to induce a strain in regions of the drift region adjoining the respective second trench,
wherein the second trenches are at least partially filled with a strain inducing material such that at least sidewalls and a bottom of each of the second trenches are covered by a strain inducing material.

2. The transistor device of claim 1, wherein the strain inducing material has a lower thermal expansion coefficient than a semiconductor material of the semiconductor body.

3. The transistor device of claim 2, wherein the strain inducing material comprises at least one of:
a semiconductor oxide;
silicon carbide;
carbon; and
glass.

4. The transistor device of claim 1, wherein the first trenches define a plurality of mesa regions in the semiconductor body, and wherein at least one of the second trenches is arranged in each of the mesa regions.

5. The transistor device of claim 4, wherein each mesa region comprises at least one of the source regions and the respective body region.

6. The transistor device of claim 1, wherein the first trenches are parallel to one another, and wherein each mesa region is formed between a respective pair of neighboring ones of the first trenches.

7. The transistor device of claim 6, wherein each mesa region comprises at least one of the source regions and the respective body region.

8. The transistor device of claim 1, wherein the first trenches form a grid, and wherein each mesa region is formed in a grid opening.

9. The transistor device of claim 8, wherein each mesa region comprises at least one of the source regions and the respective body region.

10. The transistor device of claim 1, further comprising:
field electrodes arranged in the first trenches adjacent to the drift region and dielectrically insulated from the drift region by a field electrode dielectric.

11. The transistor device of claim 10, wherein the strain inducing material is thicker than the field electrode dielectric.

12. The transistor device of claim 1, wherein the strain inducing material entirely fills the second trenches.

13. The transistor device of claim 1, wherein the strain inducing material comprises:
a first strain inducing material covering the sidewalls and the bottom of the second trenches; and
a second strain inducing material different from the first strain inducing material and formed on top of the first strain inducing material.

14. The transistor device of claim 13, wherein the second strain inducing material fills a residual trench formed by the first strain inducing material.

15. The transistor device of claim 1, wherein the second trenches further include an electrically conducting material formed on top of the strain inducing material.

16. The transistor device of claim 1, wherein the second trenches each further include a void surrounded by the strain inducing material.

17. The transistor device of claim 1, further comprising:
contact electrodes arranged in the second trenches,
wherein each of the contact electrodes adjoins at least one source region and at least one body region and is connected to a source node of the transistor device.

18. A method for forming a transistor device, the method comprising:
forming first trenches and second trenches in a semiconductor body and each extending from a first surface of the semiconductor body into the semiconductor body;
forming a drift region adjoining each of the second trenches;
forming source regions separated from the drift region by a respective body region; and
forming gate electrodes in the first trenches adjacent to at least one of the body regions and dielectrically insulated from the at least one of the body regions by a gate dielectric,
wherein forming the second trenches comprises forming the second trenches such that each of the second trenches is configured to induce a strain in regions of the drift region adjoining the respective second trench,
wherein forming the second trenches further comprises at least partially filling the second trenches with a strain inducing material such that at least sidewalls and a bottom of each of the second trenches are covered by a strain inducing material.

19. The method of claim 18, wherein at least partially filling the second trenches with the strain inducing material comprises a high temperature process, and wherein the strain inducing material has a lower thermal expansion coefficient than a semiconductor material of the semiconductor body.
